(19) United States
(12) Patent Application Publication
(10) Pub. No.: US 2007/0287222 A1
(43) Pub. Date: Dec. 13, 2007

(54) Method of fixing curved circuit board and wire bonding apparatus

(75) Inventor: Ryuichi Natsume, Tachikawa-shi (JP)

Correspondence Address: QUINN EMANUEL;KODA & ANDROLIA, 865 S. FIGUEROA STREET, 10TH FLOOR, LOS ANGELES, CA, 90017, US

(73) Assignee: Kabushiki Kaisha Shinkawa

(21) Appl. No.: 11/810,189

(22) Filed: Jun. 5, 2007

(30) Foreign Application Priority Data
Jun. 7, 2006 (JP) 2006-159007

(51) Int. Cl. H01L 21/16

(52) U.S. Cl. 438/104; 438/106; 29/841

(57) ABSTRACT

A method of holding a curved circuit board in a flat fashion and a wire bonding apparatus thereof, including suction cavities provided in a suction stage to which a curved circuit board is suctioned. While evacuating air from the vacuum suction cavities, a capillary attached to the tip end of a bonding arm is lowered to press a part of the curved circuit board down thus having at least one of the vacuum suction cavities sealed by the circuit board, allowing the remaining vacuum suction cavities to be sealed successively so that the curved circuit board is straightened to be flat and suction-held on the suction stage. The vacuum suction cavities are sealed with by straightened circuit board, and the circuit board is held on the suction stage in place.

### BACKGROUND OF THE INVENTION

The present invention relates to a method of suctioning a circuit board in place on a suction stage of a wire bonding apparatus and to a wire bonding apparatus executing the method.

A typical wire bonder that connects a circuit board and a semiconductor die mounted on the circuit board by a wire performs wire-bonding while suctioning a lead frame being transferred by vacuum and fixing the lead frame to the upper face of a suction stage. On the other hand, with recent demands for thinned semiconductor packages with improved functionalities and manufacturing efficiency, circuit boards are increasingly thinned and large-sized and multi-layer mounting of dies or so-called stacking is more and more commonly employed. However, a thinned circuit board often involves a curvature or warpage, resulting in a case in which the wire bonding cannot be performed because it is not possible to suction and fix such a circuit board to a suction stage by vacuum.

In order to ensure suctioning and fixing of the curved circuit board provided with a semiconductor die to the suction stage, there is a suction fixation apparatus that moves a suction tube upward and downward. The suction tube has a vacuum suction hole therein and penetrates through the suction stage. This apparatus is such that, when the curved circuit board is mounted with the semiconductor die and transferred to the suction stage, the suction tube is raised so as to be in contact with the circuit board and to suction the circuit board with the vacuum suction hole, then the suction tube is lowered to suction and fix the circuit board with the vacuum suction hole of the substrate suction surface (for example, see Japanese Patent Application Unexamined Publication No. 2000-138253).

Further, there is a method with which a bellow-type vacuum gripper is attached movably up and down through a penetrating hole in the suction stage so as to draw the circuit board to the substrate suction surface (for example, see Japanese Patent Application Unexamined Publication No. 2001-203222, which corresponds to European Patent Publication Nos. 1109205A1 and 1109207A1).

In wire bonding, there is a case in which either the circuit board or the semiconductor die on the circuit board is required to be heated when connecting a wire to the circuit board. However, an arrangement for suctioning the circuit board of the conventional art shown in Japanese Patent Application Unexamined Publication No. 2000-138253 or 2001-203222 is provided with an up-down moving arrangement for moving up and down the suction tube and the vacuum gripper at a lower portion of the suction stage. Therefore, such an arrangement cannot be provided with a heating arrangement at the lower portion of the suction stage, and consequently cannot be used for a bonding apparatus that performs bonding and heating at the same time.

For this reason, a method is proposed with which the circuit board is pressed down to the suction stage from an upper face of the circuit board instead of drawing the circuit board up on the suction stage from the bottom of the suction stage.

For example, as shown in FIG. 6, there is a method with which the circuit board 15 is suctioned and fixed through a vacuum suction hole 27 by blowing air from an air nozzle 71 provided above the circuit board 15 to a curved circuit board 15 that is transferred on a suction stage 23 along a transfer guides 22 so that the circuit board 15 is pressed down to a substrate suction surface 23a of the suction stage 23 (for example, see Japanese Patent Application Unexamined Publication No. 2000-138253).

Further, in the method shown in FIGS. 7(a) through 7(c) both ends of the circuit board 15 mounted with a semiconductor die 14 are gripped by gripper elements 73a and 73b of the grippers 73, respectively, so that the circuit board 15 is pulled to both sides to be flattened, and then the grippers 73 are moved down to press the circuit board 15 to the suction stage 23. Then, the grippers 73 are moved further down so that the circuit board 15 is pressed to the substrate suction surface 23a of the suction stage 23 to be suctioned and fixed with the vacuum suction hole 27 (for example, see Japanese Patent Application Unexamined Publication No. 2001-176915).

However, in the conventional art shown in FIG. 6, there is a problem that a wire 12 connects the semiconductor die 14 and the circuit board 15 is bend by a wind pressure when air is blown from the upper face, and consequently that the wire 12 and the wire 12 are brought into contact with each other. Further, in the conventional art shown in FIGS. 7(a) through 7(c), there is a problem that the apparatus becomes large and complex because it is necessary to provide a large driving arrangement besides the suction stage 23 even though a gripper driving arrangement is not necessary at a lower portion of the suction stage 23.

### BRIEF SUMMARY OF THE INVENTION

In view of the above noted problems, an object of the present invention is to provide a simple method and bonding apparatus capable of straightening a curved circuit board and suction-hold the circuit board in a flat fashion on a suction stage in an efficient manner.

According to the present invention, the method of fixing a curved circuit board in a wire bonding apparatus comprises the steps of: providing a suction stage having at least one vacuum suction cavity on a substrate suction surface thereof that suctions a circuit board thereon; providing a wire bonding tool attached to a tip end of a bonding arm; and pressing down the curved circuit board using the wire bonding tool to the suction stage so that the circuit board seals the at least one vacuum suction cavity.

Further, it is preferable that the method further includes a step of pressing down the curved circuit board using the wire bonding tool toward the at least one vacuum suction cavity of the suction stage.

According to the present invention, the method of fixing a curved circuit board in a wire bonding apparatus comprises the steps of: providing a suction stage having at least one vacuum suction cavity on a substrate suction surface thereof that suctions a circuit board thereon; providing a wire bonding tool attached to a tip end of a bonding arm; a circuit board setting step for activating a vacuum apparatus after confirming the position of the curved circuit board that is transferred onto the suction stage; a ball formation step for forming a tip end of a wire that is inserted through the wire bonding tool into a ball after the circuit board setting step; a circuit board pressing position setting step for setting a position in an X-Y direction after the ball formation step, at which position the curved circuit board is to be pressed down; a bonding tool moving step for moving the wire bonding tool to the position in the X-Y direction that has been set in the circuit board pressing position setting step; a circuit board pressing step for pressing down the curved circuit board to the suction stage by moving the wire bonding tool downwardly after the bonding tool moving step; a vacuum suction state confirming step for confirming the state of vacuum suction after the circuit board pressing step; and a preliminary bonding step for performing preliminary bonding for the ball after the vacuum suction state confirming step.

Further, it is preferable that the method further includes a circuit board pressing position setting changing step for changing the position in the X-Y direction at which the curved circuit board is pressed down when the state of the vacuum suction is not confirmed in the vacuum suction state confirming step.

It is also preferable that the ball is for pressing down the curved circuit board, and the diameter of the ball is larger than a ball for normal wire bonding.

According to the present invention, the wire bonding apparatus comprises a suction stage having at least one vacuum suction cavity on a substrate suction surface thereof that suctions a circuit board thereon; a wire bonding tool attached to a tip end of a bonding arm; and a computer for controlling the wire bonding apparatus, the computer including, a circuit board setting means for activating a vacuum apparatus after confirming a position of the curved circuit board that is transferred onto the suction stage; a ball formation means for forming the tip end of a wire that is inserted through the wire bonding tool into a ball; a circuit board pressing position setting means for setting a position in an X-Y direction, at which position the curved circuit board is pressed down; a bonding tool moving means for moving the wire bonding tool to the position in the X-Y direction that has been set by the circuit board pressing position setting means; a circuit board pressing means for pressing down the curved circuit board to the suction stage by moving the wire bonding tool downwardly; a vacuum suction state confirming means for confirming the state of vacuum suction; and a preliminary bonding means for performing preliminary bonding for the ball.

Further, it is preferable that the computer further includes a circuit board pressing position setting changing means for changing the position in the X-Y direction at which the curved circuit board is pressed down when the state of the vacuum suction is not confirmed by the vacuum suction state confirming means.

It is also preferable that the ball is for pressing down the curved circuit board, and the diameter of the ball is larger than a ball used for normal wire bonding.

The present invention provides an advantageous effect that a curved circuit board can be efficiently fixed to a suction stage using a simple method and bonding apparatus.

### BRIEF DESCRIPTION OF THE SEVERAL VIEWS OF THE DRAWINGS

FIG. 1 is a diagram showing a system structure of a wire bonder to which a method of fixing a curved circuit board and a program therefor according to the present invention are applied;

FIG. 2 is a top plan view showing the upper face of a suction stage of the wire bonder shown in FIG. 1;

FIG. 3 is a cross-sectional view of the suction stage of the wire bonder shown in FIG. 1;

FIG. 4 is a flowchart of an embodiment according to the present invention;

FIG. 5a is an illustrative view showing a state in which the curved circuit board is set;

FIG. 5b is an illustrative view showing a state in which the capillary is moved to a position at which the curved circuit board is pressed downward;

FIG. 5c is an illustrative view showing a state in which the capillary starts pressing the curved circuit board downward;

FIG. 5d is an illustrative view showing a state of the curved circuit board when the capillary reaches a position at which the downward movement stops;

FIG. 5e is an illustrative view showing a state in which the curved circuit board is suctioned and fixed;

FIG. 6 is a diagram illustrating a method of fixing a circuit board in conventional art; and

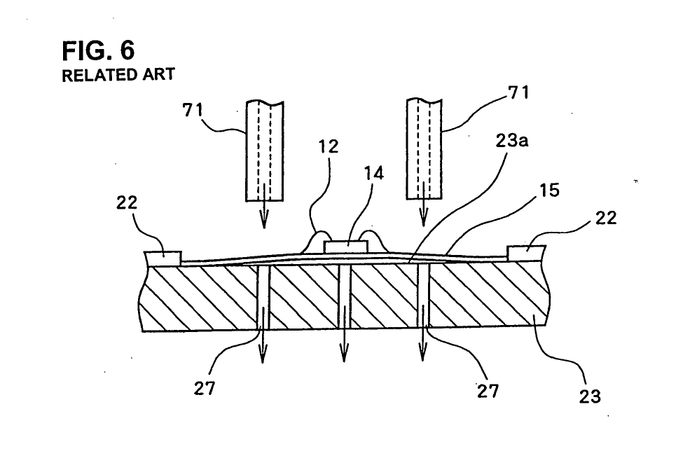

FIGS. 7(a) through 7(c) are diagrams illustrating another method of fixing a circuit board in conventional art.

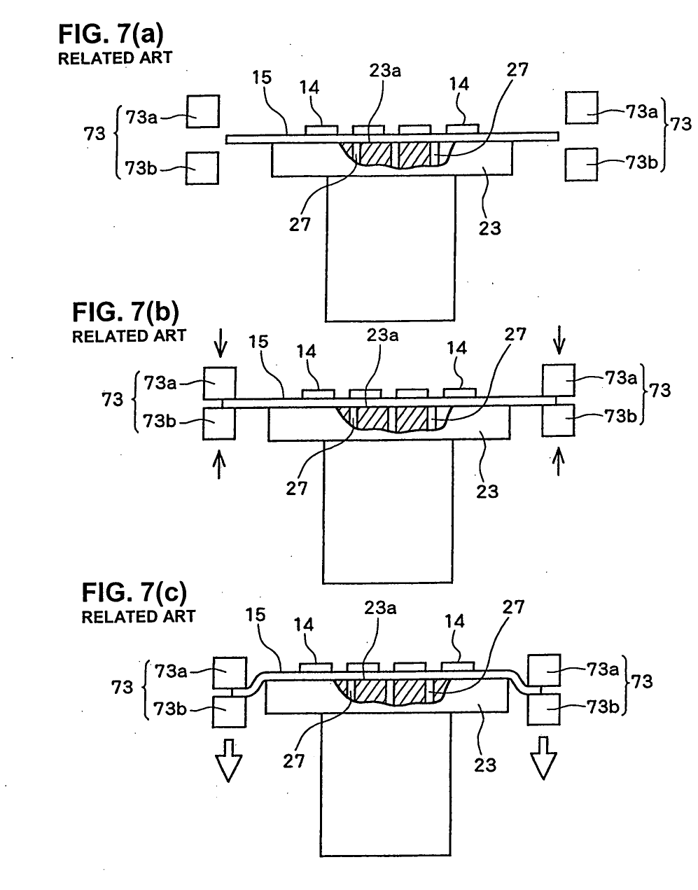

### DETAILED DESCRIPTION OF THE INVENTION

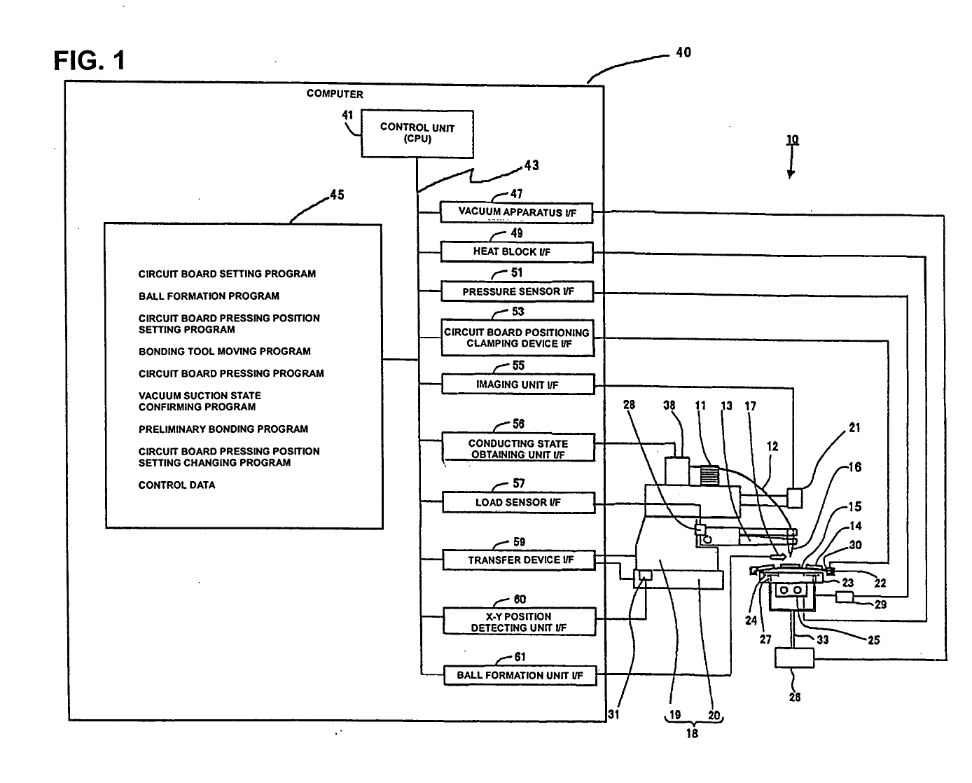

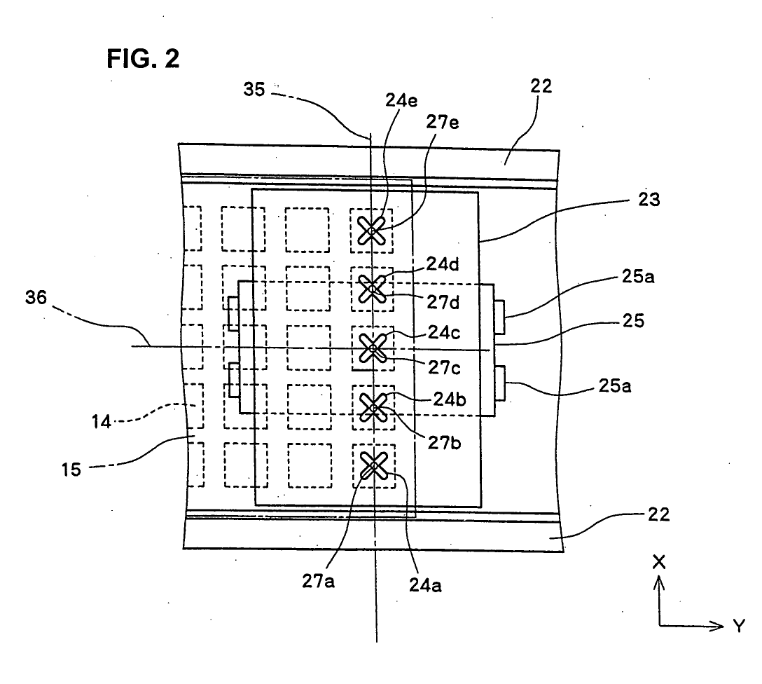

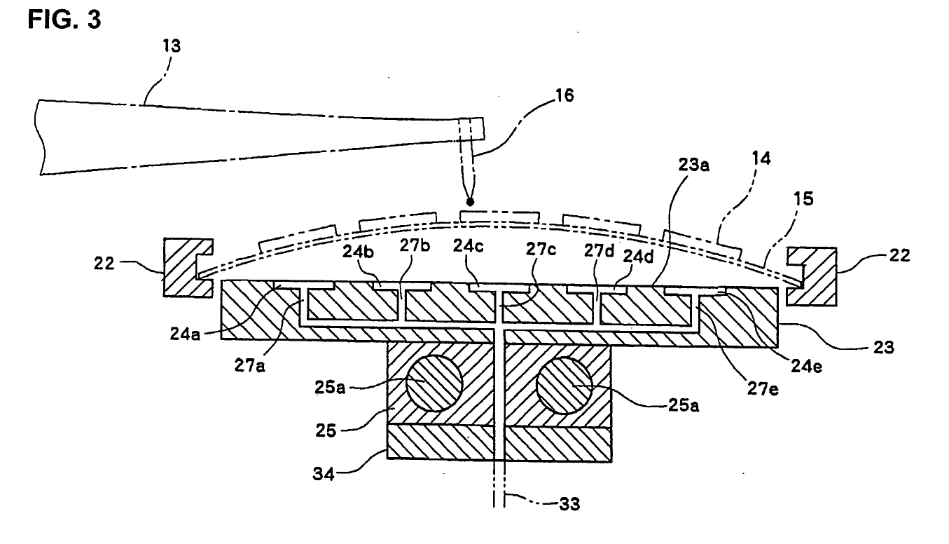

Hereinafter, preferred embodiments of the present invention will be concretely described with reference to the accompanying drawings. FIG. 1 is a diagram showing a system structure of a wire bonder to which a method of fixing a curved circuit board and a program therefor according to the embodiment of the present invention are applied. FIG. 2 is a top plan view showing the upper face of a suction stage of the wire bonder. FIG. 3 is a cross-sectional view of the suction stage of the wire bonder taken along the centerline 35 in an X-direction shown in FIG. 2.

As shown in FIG. 1, a wire bonder 10 is structured such that a bonding head 19 is disposed on an X-Y table 20, and the bonding head 19 is provided with a bonding arm 13 whose tip end is driven by a motor in a Z direction that is an up-down direction. A capillary 16 which is a bonding tool is attached to the bonding arm 13. The X-Y table 20 and the bonding head 19 structures a transfer device 18, which is able to move the bonding head 19 to any given positions within a horizontal plane (X-Y plane) using the X-Y table 20. The transfer device 18 is further able to freely move the capillary 16 attached to the tip end of the bonding arm 13 in the X, Y, and Z directions when the bonding arm 13 that is attached to the transfer device 18 is activated.

The X-Y table 20 is provided with an X-Y position detecting unit 31 that detects a position of the tip end of the capillary 16 in the X-Y direction. This X-Y position detecting unit 31 detects an X-Y coordinate position of a predetermined portion of the bonding head 19 and corrects the distance between the predetermined portion and the tip end of the capillary 16 in the X-Y direction, thereby detecting an X-Y position of the tip end of the capillary 16. The X-Y position detecting unit 31 can be of a noncontact type such as electrical or optical, or of a contact type such as mechanical. Further, the X-Y position detecting unit 31 can be an X-Y position sensor that can directory measure the position of the tip end of the capillary 16 without correcting the measured value of the X-Y position of the predetermined position of the bonding head 19, if it is possible to measure the X-Y position of the tip end of the capillary 16. Moreover, the X-Y position detecting unit 31 can be a linear scale.

The bonding head 19 is provided with a load sensor 28 that detects a load on the tip end of the capillary 16.

A wire 12 is inserted through the capillary 16 at the tip of the bonding arm 13. The wire 12 is wound around a spool 11. The wire 12 that is wound around the spool 11 is connected to a conducting state obtaining unit 38 that obtains a conducting state either between the wire 12 and a semiconductor die 14, or between the wire 12 and a circuit board 15.

In the vicinity of the tip end of the capillary 16, a ball formation unit 17 is provided for forming a tip end of the wire 12 into a ball. The ball formation unit 17 can be an electric flame off probe that causes a discharge between ball formation unit 17 and the wire 12 to form a ball, or can be a gas torch.

Furthermore, the bonding head 19 is attached with an imaging unit 21 that images the capillary 16, the semiconductor die 14, and the circuit board 15.

Below the capillary 16, a suction stage 23 for suctioning and fixing the circuit board 15 mounted with the semiconductor die 14 is attached to a wire bonder frame that is not shown in the drawing.

Transfer guides 22 that guide the circuit board 15 are fixed to both sides of the suction stage 23, respectively, and the circuit board positioning clamping device 30 that holds so as to sandwich the circuit board 15 and move to a predetermined position is attached in the vicinity of the transfer guides 22. The suction stage 23 is provided with a plurality of vacuum suction cavities 24, which are evacuated when the upper face of the suction stage 23 is sealed by the circuit board 15, and a vacuum suction hole 27 is opened at a lower portion of each vacuum suction cavity 24. The vacuum suction hole 27 is connected to a vacuum apparatus 26 via a vacuum plumbing 33.

A pressure sensor 29 that detects the pressure in the vacuum suction cavities 24 is provided in the vicinity of the suction stage 23. The pressure sensor 29 can consecutively output a signal of a measured pressure. Alternatively, the pressure sensor 29 can be a pressure switch that outputs a signal when the pressure reaches a predetermined level. A plurality of pressure sensors 29 can be provided so that each pressure sensor 29 detects the pressure of each vacuum suction cavity 24, or a single pressure sensor 29 can be provided at the vacuum suction hole 27 under the vacuum suction cavities 24. Further, the pressure sensor 29 can be provided at one or more portions of the vacuum plumbing 33 that connects the vacuum apparatus 26 and the vacuum suction hole 27.

In addition, a heat block 25 that heats the circuit board 15 mounted with the semiconductor die 14 that is suctioned by vacuum is attached to the lower portion the suction stage 23.

The transfer device 18 is connected to a transfer device interface 59, the ball formation unit 17 is connected to a ball formation unit interface 61, the conducting state obtaining unit 38 is connected to a conducting state obtaining unit interface 56, and the X-Y position detecting unit 31 is connected to an X-Y position detecting unit interface 60. In addition, the load sensor 28 is connected to a load sensor interface 57, the imaging unit 21 is connected to an imaging unit interface 55, the circuit board positioning clamping device 30 is connected to a circuit board positioning clamping device interface 53, and the pressure sensor 29 is connected to a pressure sensor interface 51. Furthermore, the vacuum apparatus 26 is connected to a vacuum apparatus interface 47, and the heat block 25 is connected to a heat block interface 49.

Each one of the above-described interfaces is connected through a data bus 43 to a control unit 41 of a computer 40 for controlling bonding actions. The above-described interfaces are respectively component parts of the computer 40. The control unit 41 of the computer 40 includes a CPU for controlling the bonding action. Further, to the data bus 43 is connected a memory unit 45 for storing control data and programs including a circuit board setting program, a ball formation program, a circuit board pressing position setting program, a bonding tool moving program, a circuit board pressing program, a vacuum suction state confirming program, preliminary bonding program, and a circuit board pressing position setting changing program.

Referring to FIG. 2 and FIG. 3, the suction stage 23 and related portions of the wire bonder 10 will be described below in detail. In the following description, as shown in FIG. 2, a direction across the horizontal plane along which the circuit board is carried is referred to as a Y direction, and a direction perpendicular to the direction along which the circuit board is carried is referred to as an X direction.

As shown in FIG. 2, the suction stage 23 is a flat rectangular plate that is disposed between the transfer guides 22. The suction stage 23 has a plurality of vacuum suction cavities 24a-24e lined up along the X-direction centerline 35 in the middle of a substrate suction surface 23a of the suction stage 23. Each of the vacuum suction cavities 24a-24e is structured by a pair of grooves with a rectangular vertical cross-section that cross with each other such that the grooves form substantially 45 degrees with the X-direction center line 35 and the Y-direction center line 36, respectively, so that the cross-section of each cavity taken along the horizontal plane is in an X shape. Vacuum suction holes 27a-27e respectively open up at center portions of the X-shaped vacuum suction cavities 24a-24e.

Each groove in each of the X-shaped cavities 24a-24e is slightly shorter than a diagonal line of the semiconductor die 14 mounted to the circuit board 15. The shape of the vertical section of the grooves of the vacuum suction cavities 24a-24e is not limited to the rectangular shape, and can be any other shape such as a semicircle. Moreover, the horizontal cross-section is not limited to the X shape as mentioned above, and can be any other shape such as either a cross shape with the grooves forming an angle other than 45 degrees to the X-direction center line 35 and the Y-direction center line 36, respectively, or a star shape having more than two grooves, as long as the grooves extend radially from the center portion of each of the vacuum suction holes 27a-27e so that the circuit board 15 can be efficiently suctioned.

In bonding, the position of the circuit board 15 is set so that the center of the semiconductor die 14 mounted to the circuit board 15 is on the X-direction center line 35. This position of the circuit board 15 is referred to as a bonding position.

FIG. 3 is a cross-sectional view of the suction stage 23 taken along the X-direction centerline 35 as shown in FIG. 2, and each of the vacuum suction cavities 24a-24e is shown in a cross-section in the lengthwise direction of the groove.

As shown in FIG. 3, the suction stage 23 is overlaid on and fixed to the heat block 25 that is fixed to a base 34. Each of the vacuum suction holes 27a-27e at the center portion of each of the vacuum suction cavities 24a-24e is connected, within the suction stage 23, to a header, and guided from the suction stage 23 to the lower portion of the base 34. The vacuum suction holes 27a-27e are connected to the vacuum plumbing 33 at the lower portion of the base 34. Instead of structuring a header within the suction stage 23, each of the vacuum suction holes 27a-27e can be structured so as to penetrate to the lower portion of the suction stage 23 and the vacuum plumbing 33 is connected to each of the penetrating portions and bound up into a single header connected to the vacuum apparatus 26.

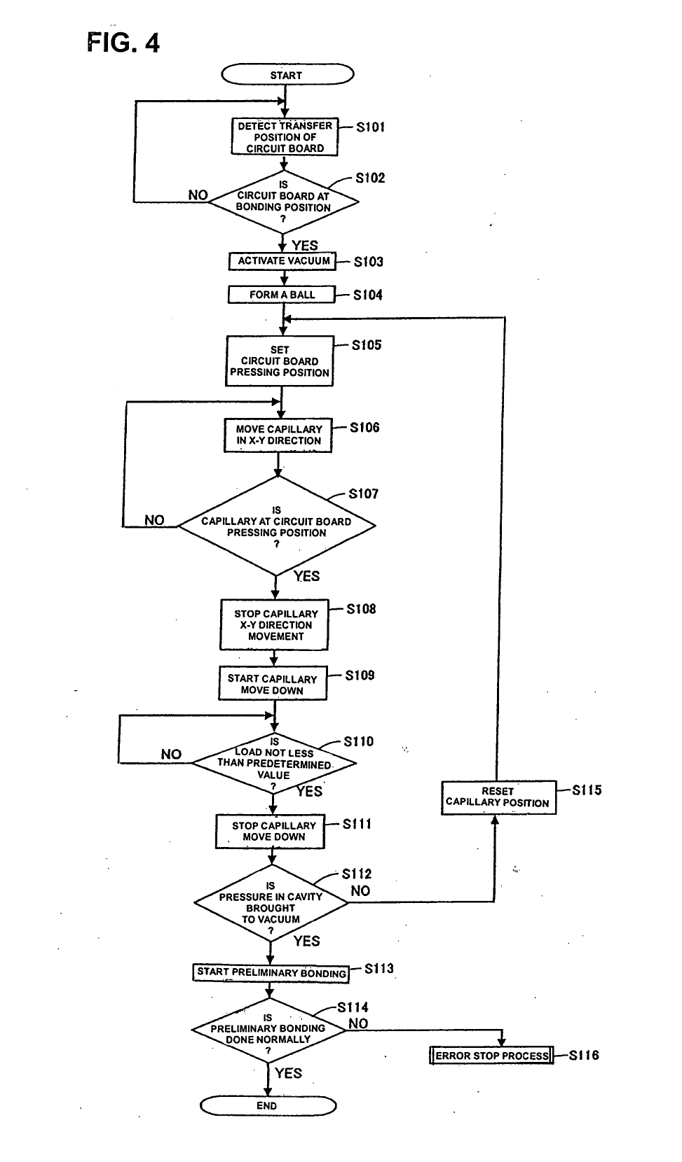

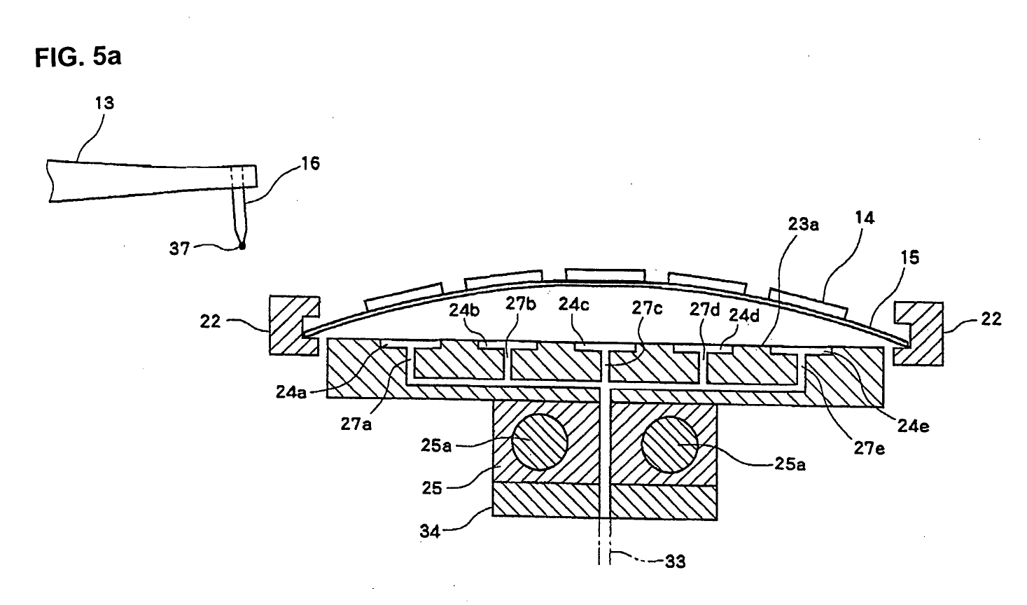

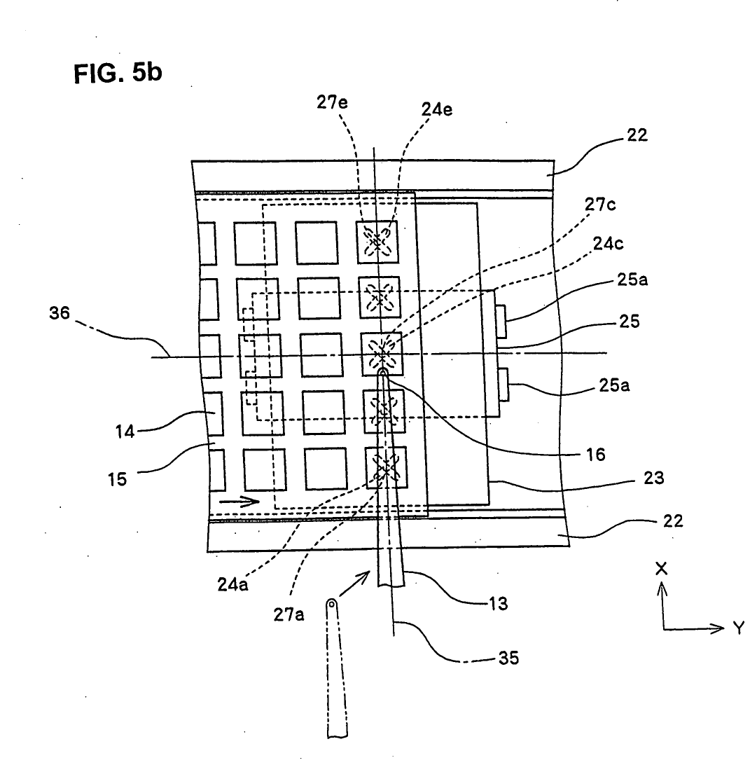

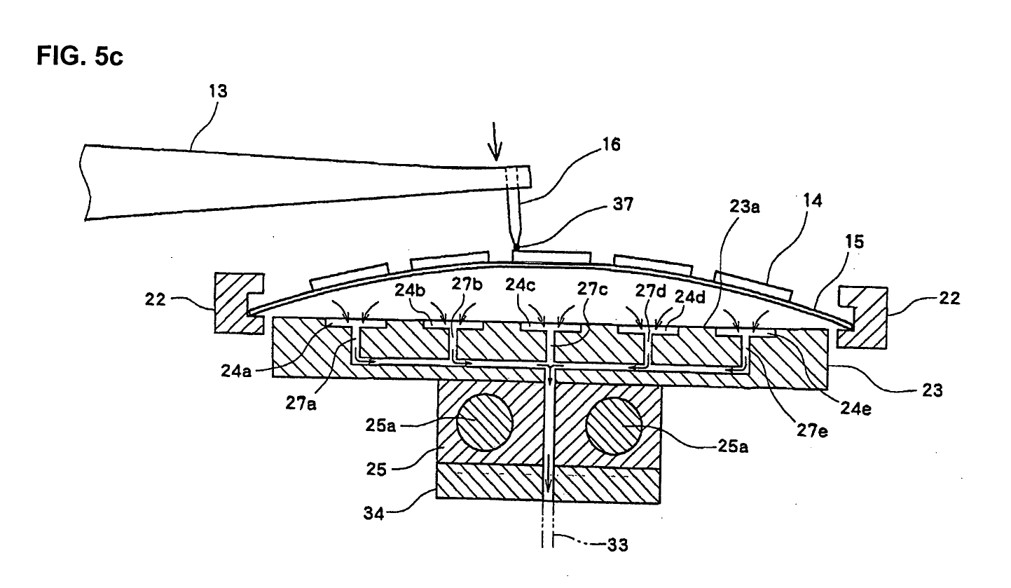

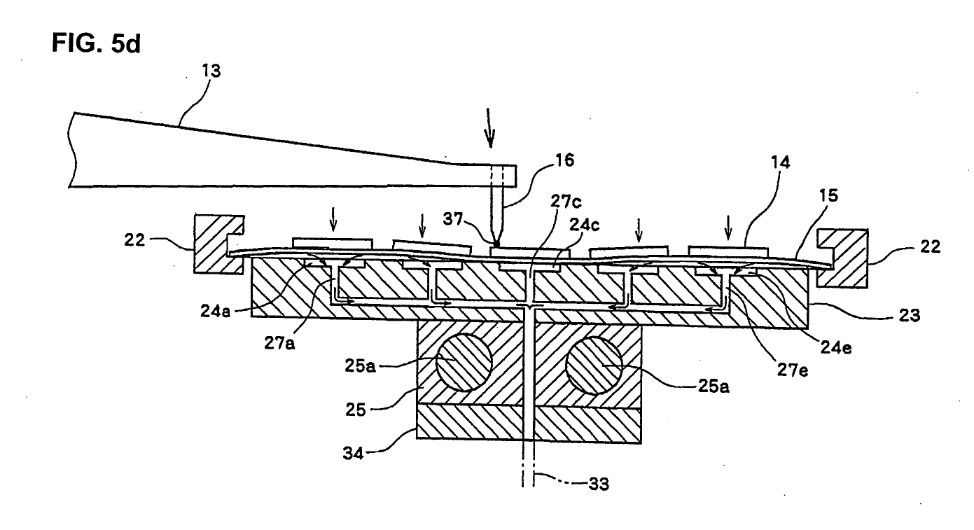

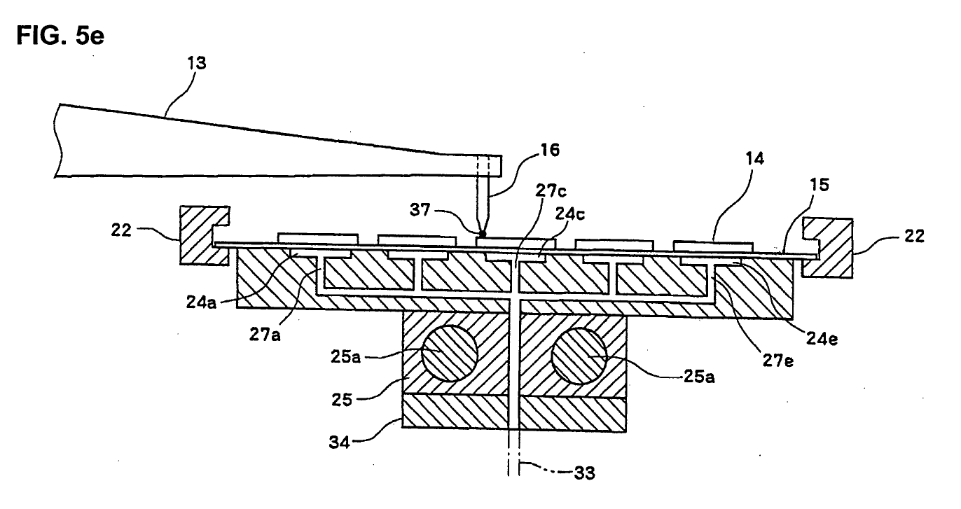

Next, the operation in the method of fixing a curved circuit board and the program therefor will be described with reference to FIG. 4 and FIGS. 5a to 5e. FIG. 4 is a flowchart showing the operation in this embodiment, and FIGS. 5a to 5e are illustrative views showing the operational states.

As shown in FIG. 5a, when the wire bonder 10 is activated, the curved circuit board 15 on which the semiconductor dies 14 are mounted is guided by the transfer guides 22 at both sides of the suction stage 23, and transferred to the suction stage 23. Because the circuit board 15 curves to a large degree as being a thin substrate, there is a gap between the circuit board 15 and the substrate suction surface 23a of the suction stage 23. Further, the bonding arm 13 provided with the capillary 16 at the tip end stands by at a standby position that is not on a transfer path of the circuit board 15, with the capillary 16 at a rising position. In this embodiment, the standby position of the bonding arm 13 is a position at which the capillary 16 at the tip end comes outside the area between the transfer guides 22. However, this standby position can be within the area between the two transfer guides 22, as long as the capillary 16 at the tip end at the standby position does not interfere the curved circuit board 15 that is being transferred. Moreover, when the wire bonder 10 is activated, the control unit 41 of the computer 40 outputs an instruction for starting up the heat block to the heat block interface 49, which then activates a heat source 25a to start heating the heat block 25 according to this instruction.

In Step S101 in FIG. 4, when the circuit board 15 is being transferred by the circuit board positioning clamping device 30, whether or not the circuit board 15 is carried to a predetermined position by the circuit board positioning clamping device 30 is detected, and a detection signal of the detection is converted by the circuit board positioning clamping device interface 53 into a signal that can be inputted to the control unit 41 of the computer 40, and then inputted to the control unit 41. The control unit 41 detects whether or not the circuit board 15 has been reached the bonding position as shown in FIG. 5b, based on this signal using the imaging unit 21.

When the circuit board 15 reaches the bonding position, the circuit board positioning clamping device 30 transmits a bonding position reaching signal, which is inputted to the control unit 41 from the circuit board positioning clamping device interface 53 of the computer 40. In the next Step S102 in FIG. 4, the control unit 41 determines based on the input of the signal that the circuit board 15 has reached the predetermined bonding position, and outputs an instruction to stop the transfer operation to a transfer apparatus that is not depicted in the drawing. Then, the circuit board 15 stops at the bonding position.

Next, the control unit 41 of the computer 40 activates the vacuum apparatus 26 in Step S103. Because there is a gap between the circuit board 15 transferred to the bonding position and the substrate suction surface 23a as shown in FIG. 5a, the pressure inside each one of the vacuum suction cavities 24a-24e is not brought to vacuum even after the air in each of the vacuum suction holes 27a-27e is evacuated by the vacuum apparatus 26, and it is not possible to suction and fix the circuit board 15. Consequently, the gap between the circuit board 15 and the substrate suction surface 23a remains the same.

In the next Step S104 in FIG. 4, the control unit 41 of the computer 40 outputs a signal for ball formation to the ball formation unit interface 61. In response to the ball formation signal, the ball formation unit interface 61 causes a discharge between the wire 12 lead out at the tip end of the capillary 16 and the ball formation unit 17 to form a ball 37 as shown in FIG. 5a. The formation of the ball 37 is for a smooth shift to a bonding step after the circuit board 15 is suctioned and fixed in place. Further, in forming the ball 37, it is also preferable to cause the discharge with greater power than in forming a common ball for bonding to form the ball 37 for pressing down that is larger than the common ball for bonding. The formation of a larger ball increases an area that presses down the curved circuit board 15, allowing the ball to press the circuit board 15 down more efficiently.

In the next Step S105 in FIG. 4, the control unit 41 of the computer 40 sets a most suitable pressing position of the circuit board 15 in an X-Y direction based on data of the circuit board 15 that has been inputted into the memory unit 45 in advance. In this embodiment, the pressing position is set to an end portion of the semiconductor die 14 disposed at the center of the circuit board 15. This is because the position in the vicinity of the center of the circuit board 15 is appropriate to press the entirety of the circuit board down to the suction stage 23 evenly, and because no semiconductor circuit element is provided at the end portion of the semiconductor die 14 so that the pressing down can not cause any damage to the semiconductor circuit element of the die. Further, the pressing position can be any position on the circuit board 15 at which the semiconductor die 14 is not disposed as long as one of the vacuum suction cavities 24a-24e can be sealed. In addition, this pressing position can be immediately above one of the vacuum suction holes 27a-27c, depending on the type of the semiconductor die 14 and the type of the circuit board 15. This immediately-above position is a position at which the circuit board 15 can be pressed most directly down to a the center of each of the vacuum suction cavities 24a-24e than at other positions, and the circuit board 15 can be more effectively suctioned.

Once the pressing position of the circuit board 15 is set, in Step S106, the control unit 41 of the computer 40 outputs, to the transfer device interface 59, an instruction for moving the position of the tip end of the capillary 16 toward the set position in the X-Y direction. As shown in FIG. 5b, the transfer device interface 59 (see FIG. 1) drives the X-Y table 20 based on this instruction, and starts moving the bonding head 19 so that the capillary 16 at the tip end of the bonding arm 13 comes to the pressing position that has been set in the X-Y direction. The control unit 41 obtains the detection signal from the X-Y position detecting unit 31 through the X-Y position detecting unit interface 60 in Step S107, and monitors the difference between the position of the tip end of the capillary 16 and the pressing position. Further, the difference between the pressing position and an instructed value computed by the computer can be monitored by taking images of the capillary 16, the semiconductor die 14, and the circuit board 15 using the imaging unit 21, inputting the image data to the control unit 41 through the imaging unit interface 55, and obtaining the tip end position of the capillary 16 based on image processing using the control unit 41. Then, when the control unit 41 determines that the difference has crossed over a threshold value, the control unit 41 inputs an instruction to stop the movement of the tip end position of the capillary 16 to the transfer device interface 59 in Step S108. In response to the instruction, the transfer device interface 59 stops the movement of the bonding head 19, and consequently stops the movement of the tip end position of the capillary 16 in the X-Y direction. When the movement of the bonding head 19 stops, the tip end position of the capillary 16 is at the pressing position which is at the end portion of the semiconductor die 14 disposed at the center of the circuit board 15 as shown in FIG. 5b, and the tip end of the capillary 16 is at a raised position away from the circuit board 15 or the semiconductor die 14.

In the next Step S109 in FIG. 4, the control unit 41 of the computer 40 outputs, to the transfer device interface 59, an instruction for moving the tip end of the capillary 16 downward. Based on this instruction, the transfer device interface 59 drives a motor, which is for driving the bonding arm 13 and is provided in the bonding head 19, to output a signal for moving the tip end of the capillary 16 downward. Then, the motor of the bonding head 19 is driven and the bonding arm 13 starts to rotate downwardly. A signal for detecting the load at the tip end of the capillary by the load sensor 28 is inputted from the load sensor interface 57 to the control unit 41. The control unit 41 monitors the difference between the signal and a predetermined grounding load of the capillary in Step S110. The grounding load is a load detected when the tip end of the capillary 16 grounds (or touches the pressing position), which is smaller than a pressure-bonding load of a wire in normal bonding so that the ball 37 at the tip end of the capillary is prevented from being pressure-bonded to the semiconductor die 14 or the circuit board 15 by pressing down the circuit board 15.

As shown in FIG. 5c, the tip end of the capillary 16 starts to move down to the curved circuit board 15 by the downward movement of the bonding arm 13. Then, the ball 37 formed at the wire at the tip end of the capillary is brought into contact with the semiconductor die 14. In this state, there is a gap between the circuit board 15 and the substrate suction surface 23a, and air flows through the gap to the vacuum apparatus 26 (see FIG. 1), and accordingly, any of the vacuum suction cavities 24a-24e is not sealed, and the circuit board 15 cannot be suctioned by vacuum.

During the downward movement of the bonding arm 13, the control unit 41 of the computer 40 (see FIG. 1) continues monitoring whether or not the load at the tip end of the capillary is equal to or more than the predetermined grounding load based on the signal inputted from the load sensor 28. Then, when the difference between the input signal from the load sensor 28 and the grounding load crosses over the predetermined threshold value, the control unit 41 determines that the capillary 16 is grounded and outputs an instruction for stopping the downward movement of the capillary 16 to the transfer device interface 59 in Step S111 in FIG. 4. According to this instruction, the transfer device 18 stops the downward movement of the bonding arm 13 of the bonding head 19, to stop the downward movement of the capillary 16. Alternatively, the detection as to whether or not the capillary 16 is grounded can be made by detecting conducting current using the conducting state obtaining unit 38. In this case, when the capillary 16 is grounded, a current for detecting the conducting state flows through the wire 12. The conducting current from the wire 12 to the semiconductor die 14 or the circuit board 15 is detected by the conducting state obtaining unit 38, and the detected signal is inputted to the control unit 41 from the conducting state obtaining unit interface 56. Based on the signal input, the control unit 41 detects the grounding of the capillary 16 to stop the downward movement of the capillary 16. The conducting state obtaining unit 38 can be a direct type that detects changes in a direct current between the wire 12 and the semiconductor die 14 or the circuit board 15, or can be an alternating type that detects changes in an alternating current.

After the above-described process, as shown in FIG. 5d, by the downward movement of the capillary 16, the central portion of the circuit board 15 is pressed down to the substrate suction surface 23a of the suction stage 23, the portion of the circuit board 15 below the semiconductor die 14 in the center of the circuit board 15 is brought into contact with the substrate suction surface 23a, and the circuit board 15 covers the upper face of the vacuum suction cavity 24c. In this situation, a portion of the air flow path from the vacuum suction cavities 24a-24e to the vacuum apparatus 26 is blocked, and an amount of air flow to the vacuum apparatus 26 decreases. Consequently, the pressure in all the vacuum suction cavities 24a-24e is reduced. Then, when the pressure in all the vacuum suction cavities 24a-24e becomes lower than the atmosphere pressure, the circuit board 15 starts to be pressed to the suction stage 23 by the atmosphere pressure. This causes the lower face of the circuit board 15 to closely attach in the vicinity of the vacuum suction cavity 24c where the gap between the lower face of the circuit board 15 and the substrate suction surface 23a is the smallest, thereby sealing the upper face of the vacuum suction cavity 24c. By this, the central portion of the circuit board 15 is suctioned to the substrate suction surface 23a. As shown in FIG. 5d, the circuit board 15 above the vacuum suction cavities 24a, 24b, 24d, and 24e is not closely attached to the substrate suction surface 23a. However, because the vacuum suction cavity 24c is closed (substantially) entirely, the amount of air flow evacuated by the vacuum apparatus 26 is further decreases, and the pressure in the entire vacuum suction cavities 24a-24e is further reduced. By this, the circuit board 15 over the vacuum suction cavities 24a, 24b, 24d, and 24e is pressed even more strongly to the suction stage 23 by the atmosphere pressure.

Then, when the circuit board 15 seals the upper face of any one of the vacuum suction cavities 24a, 24b, 24d, and 24e, the air does not flow from the vacuum suction cavities to the vacuum apparatus 26, resulting in further reduction in the pressure in the entire vacuum suction cavities 24a-24e to increase the difference from the atmosphere pressure. As the pressure difference increases, the strength to press the circuit board 15 down also increases, and the vacuum suction cavities 24a-24e are sealed by the circuit board 15 one by one. When all of the vacuum suction cavities 24a-24e are sealed by the circuit board 15, the circuit board 15 is completely suctioned to the suction stage by vacuum. As seen from the above, when one of the vacuum suction cavities is sealed, the pressure in the entire vacuum suction cavities is reduced in a chain reaction, and together with the pressure difference from the atmosphere pressure, the circuit board 15 is rapidly suctioned to the substrate suction surface. When all of the vacuum suction cavities 24a-24e are sealed by the circuit board 15, the circuit board 15 is suctioned and fixed to the substrate suction surface 23a as shown in FIG. 5e, and the pressures in each of the vacuum suction cavities 24a-24e, in each of the vacuum suction holes 27a-27e, and in the vacuum plumbing 33 are brought into substantially vacuum.

In Step S112, the control unit 41 of the computer 40 (see FIG. 1) obtains a pressure measured by the pressure sensor 29 as a pressure signal from the pressure sensor interface 51, and determines whether or not the difference between the pressure and a predetermined vacuum pressure has crossed over a predetermined threshold value. Then, when the difference crosses over the predetermined threshold value, the control unit 41 determines that all of the vacuum suction cavities 24a-24e are brought to vacuum and the circuit board 15 is suctioned and fixed on the suction stage 23.

After confirming the vacuum suction state of the circuit board 15, the control unit 41 of the computer 40 outputs an instruction to the transfer device interface 59 for raising and moving the capillary 16 to a preliminary bonding position, such as at the circuit board 15 or an end portion of the circuit board, at which wire bonding cannot be interfered. The transfer device 18 drives the motor for driving the bonding arm 13 to raise the bonding arm 13, and then moves the tip end of the capillary by the X-Y table to the preliminary bonding position of the circuit board 15 according to the instruction. When the tip end of the capillary reaches the preliminary bonding position, the control unit 41 moves the capillary 16 downwardly to perform bonding at the preliminary bonding position. In this case, as in the common bonding, the ball 37 formed at the tip end of the capillary 16 is pressure-bonded to the preliminary bonding position. Once the ball 37 is pressure-bonded by the capillary 16, the current for detecting the conducting state flows through the wire 12. The conducting current is detected by the conducting state obtaining unit 38, and a signal of the current is inputted to the control unit 41 through the conducting state obtaining unit interface 56. The control unit 41 determines that the ball 37 is pressure-bonded based on the input of the signal. Then, the control unit 41 raises the capillary 16 to cut the tail wire. After cutting the tail wire, the current for detecting the conducting state that has been flowed through the wire 12 stops flowing. The state in which the conducting current stops is detected by the conducting state obtaining unit 38, and a signal for the state is inputted to the control unit 41 through the conducting state obtaining unit interface 56. The control unit 41 determines that the wire 12 is normally cut based on the signal. Then, the control unit 41 determines that the preliminary bonding has been performed normally when the signal for the conductive state based on the pressure-bonding of the ball 37 and the signal based on the absence of the conducting current by the cutting of the wire are both inputted. When the preliminary bonding is normally completed in the preliminary bonding step as described above, the control unit 41 finishes the fixation program of the curved circuit board. When there is an error in the preliminary bonding in the preliminary bonding step, the control unit 41 performs an error stop process and deactivates the wire bonding apparatus in Step S116 in FIG. 4.

On the other hand, when the pressure difference as described above crosses over the predetermined threshold value, the control unit 41 of the computer 40 determines that any of the vacuum suction cavities remains unsealed and is drawing the air, and the circuit board 15 is not fully suctioned and fixed. Then, when the vacuum suction state of the circuit board 15 cannot be confirmed, the control unit 41 repeats the press down movement of the circuit board 15 in Step S112.

In Step S115 in FIG. 4, the control unit 41 of the computer 40 outputs an instruction to the transfer device interface 59 for resetting the height of the capillary to an ascending position. According to this instruction, the transfer device interface 59 drives the motor for the bonding arm 13 to raise the bonding arm 13, and resets the position of the tip end of the capillary 16 to the ascending position as an initial state. Then, the control unit 41 changes the setting of the pressing position of the circuit board in the X-Y direction in Step S105. The position can be set to an end surface of the semiconductor die 14 adjacent to the previous pressing position. Further, more than one pressure sensor 29 can be attached to the vacuum suction cavities 24a-24e, respectively, so that a position in the vicinity of a vacuum suction cavity with the largest pressure is pressed down.

Next, upon completion of the setting of the pressing position, the control unit 41 of the computer 40 again moves the tip end of the capillary 16 to the pressing position by the transfer device 18 in Step S106, and repeats the press down movement of Steps S109 to S111. Then, in Step S112, when the vacuum state of the vacuum suction cavities is confirmed, the control unit 41 determines that the circuit board 15 is suctioned to the suction stage 23. After this, the preliminary bonding step starts in Step S113, and when the preliminary bonding is completed normally, the control unit 41 ends the fixation program of the curved circuit board in Step S114.

When the circuit board 15 is suctioned and fixed to the suction stage 23, the circuit board 15 and the semiconductor die 14 are heated by the heat block 25 that is provided below the suction stage 23 and has already been heated up to a temperature at which the heating is possible, so that wire-bonding can be performed. The control unit 41 of the computer 40 runs a bonding program and performs the wire bonding between the semiconductor die 14 and the circuit board 15. When the bonding of the semiconductor dies 14 that are lined up along the X-direction center line 35 is completed, the vacuum is released to release the vacuum suction fixation of the circuit board 15. Then, the circuit board 15 is transferred till the next row of the semiconductor dies 14 comes to the X-direction center line 35, and the suction operation of the circuit board 15 is repeated in the same manner as described above.

In the bonding apparatus of the present invention describe above, the pair of transfer guides 22 are operated so as to move toward each other and away from each other so that the both side edges of the curved circuit board and straightened circuit board can be snugly held and carried smoothly thereby. In the process shown from FIG. 5a to FIG. 5e, the transfer guides 22 are gradually moved away from each other as the process proceeds.

As described above, according to this embodiment, the curved circuit board 15 can be advantageously suctioned and fixed to the suction stage 23 by vacuum in a simple and efficient manner only by changing the control program without adding any special arrangement to the wire bonder 10 of a common structure. Further, because there is no need to provide a movable arrangement below the suction stage 23, it is possible to perform suction and heating of the circuit board at the same time, thereby advantageously improving the bonding efficiency.

What is claimed is:

1. A method of fixing a curved circuit board in a wire bonding apparatus, the method comprising the steps of:
providing a suction stage having at least one vacuum suction cavity on a substrate suction surface thereof for suctioning a circuit board;
providing a wire bonding tool attached to a tip end of a bonding arm; and
pressing down a curved circuit board using the wire bonding tool to the suction stage so that the circuit board seals the at least one vacuum suction cavity.

2. The method of fixing a curved circuit board in a wire bonding apparatus according to claim 1, further comprising pressing down the curved circuit board using the wire bonding tool toward the at least one vacuum suction cavity of the suction stage.

3. A method of fixing a curved circuit board in a wire bonding apparatus, the method comprising the steps of:
providing a suction stage having at least one vacuum suction cavity on a substrate suction surface thereof for suctioning a circuit board;
providing a wire bonding tool attached to a tip end of a bonding arm;
a circuit board setting step for activating a vacuum apparatus after confirming a position of a curved circuit board that is transferred onto the suction stage;
a ball formation step for forming a tip end of a wire that is inserted through the wire bonding tool into a ball after the circuit board setting step;
a circuit board pressing position setting step for setting a position in an X-Y direction after the ball formation step, said position being for pressing down the curved circuit board;
a bonding tool moving step for moving the wire bonding tool to a position in the X-Y direction that has been set in the circuit board pressing position setting step;
a circuit board pressing step for pressing down the curved circuit board to the suction stage by moving the wire bonding tool downwardly after the bonding tool moving step;
a vacuum suction state confirming step for confirming a state of vacuum suction after the circuit board pressing step; and
a preliminary bonding step for performing preliminarily bonding for the ball after the vacuum suction state confirming step.

4. The method of fixing a curved circuit board in a wire bonding apparatus according to claim 3, further comprising a circuit board pressing position setting changing step for changing the position in the X-Y direction at which the curved circuit board is pressed down when the state of the vacuum suction is not confirmed in the vacuum suction state confirming step.

5. The method of fixing a curved circuit board in a wire bonding apparatus according to claim 3, wherein
the ball is for pressing down the curved circuit board, and a diameter of the ball is larger than a ball for normal wire bonding.

6. The method of fixing a curved circuit board in a wire bonding apparatus according to claim 4, wherein
the ball is for pressing down the curved circuit board, and a diameter of the ball is larger than a ball for normal wire bonding.

7. A wire bonding apparatus comprising:
a suction stage having at least one vacuum suction cavity on a substrate suction surface thereof for suctioning a circuit board thereon;
a wire bonding tool attached to a tip end of a bonding arm; and
a computer for controlling the wire bonding apparatus, said computer including,
a circuit board setting means for activating a vacuum apparatus after confirming a position of a curved circuit board transferred onto the suction stage;
a ball formation means for forming a tip end of a wire inserted through the wire bonding tool into a ball;
a circuit board pressing position setting means for setting a position in an X-Y direction said position being for pressing down the curved circuit board;
a bonding tool moving means for moving the wire bonding tool to the position in the X-Y direction set by the circuit board pressing position setting means;
a circuit board pressing means for pressing down the curved circuit board to the suction stage by moving the wire bonding tool downwardly;
a vacuum suction state confirming means for confirming a state of vacuum suction; and
a preliminary bonding means for performing preliminary bonding for the ball.

8. The wire bonding apparatus according to claim 7, said computer further including a circuit board pressing position setting changing means for changing the position in the X-Y direction at which the curved circuit board is pressed down when the state of the vacuum suction is not confirmed in the vacuum suction state confirming means.

9. The wire bonding apparatus according to claim 6, wherein
the ball is for pressing down the curved circuit board, a diameter of the ball being larger than a ball for normal wire bonding.

10. The wire bonding apparatus according to claim 7, wherein
the ball is for pressing down the curved circuit board, a diameter of the ball being larger than a ball for normal wire bonding.

11. A method of fixing a curved circuit board in a wire bonding apparatus including a suction stage having at least one vacuum suction cavity on a substrate suction surface thereof for suctioning a circuit board; and a wire bonding tool attached to a tip end of a bonding arm; the method comprising the steps of:
pressing down a curved circuit board using the wire bonding tool to the suction stage so that the circuit board seals the at least one vacuum suction cavity.

12. The method of fixing a curved circuit board in a wire bonding apparatus according to claim 11, further comprising a step of:
pressing down the curved circuit board using the wire bonding tool toward the at least one vacuum suction cavity of the suction stage.

13. A method of fixing a curved circuit board in a wire bonding apparatus including a suction stage having at least one vacuum suction cavity on a substrate suction surface thereof for suctioning a circuit board; and a wire bonding tool attached to a tip end of a bonding arm, the method comprising the steps of:
a circuit board setting step for activating a vacuum apparatus after confirming a position of the curved circuit board that is transferred onto the suction stage;
a ball formation step for forming a tip end of a wire that is inserted through the wire bonding tool into a ball after the circuit board setting step;
a circuit board pressing position setting step for setting a position in an X-Y direction after the ball formation step, said position being for pressing down the curved circuit board;
a bonding tool moving step for moving the wire bonding tool to a position in the X-Y direction that has been set in the circuit board pressing position setting step;
a circuit board pressing step for pressing down the curved circuit board to the suction stage by moving the wire bonding tool downwardly after the bonding tool moving step;
a vacuum suction state confirming step for confirming a state of vacuum suction after the circuit board pressing step; and
a preliminary bonding step for performing preliminary bonding for the ball after the vacuum suction state confirming step.

14. The method of fixing a curved circuit board in a wire bonding apparatus according to claim 13, further comprising
a circuit board pressing position setting changing step for changing the position in the X-Y direction at which the curved circuit board is pressed down when the state of the vacuum suction is not confirmed in the vacuum suction state confirming step.

15. The method of fixing a curved circuit board in a wire bonding apparatus according to claim 13, wherein
the ball is for pressing down the curved circuit board, and a diameter of the ball is larger than a ball for normal wire bonding.

16. The method of fixing a curved circuit board in a wire bonding apparatus according to claim 14, wherein
the ball is for pressing down the curved circuit board, and a diameter of the ball is larger than a ball for normal wire bonding.
